(19) United States
(12) Patent Application Publication
(10) Pub. No.: US 2009/0127722 A1
(43) Pub. Date: May 21, 2009

(54) Method for Processing a Spacer Structure, Method of Manufacturing an Integrated Circuit, Semiconductor Device and Intermediate Structure with at Least One Spacer Structure

(76) Inventors: Christoph Noelscher, Nuernberg (DE); Ulrich Egger, Dresden (DE); Rolf Weis, Dresden (DE); Stephan Wege, Dresden (DE); Burkhard Ludwig, Muenchen (DE)

Correspondence Address: SLATER & MATSIL, L.L.P., 17950 PRESTON ROAD, SUITE 1000, DALLAS, TX, 75252, US

(21) Appl. No.: 11/943,445

(22) Filed: Nov. 20, 2007

(51) Int. Cl. H01L 23/544; H01L 21/306

(52) U.S. Cl. 257/797; 438/8; 438/401; 257/E23.179; 257/E21.219

(57) ABSTRACT

Method for processing at least one spacer structure in a manufacturing process of a semiconductor device, wherein the at least one spacer structure is subjected to at least one etch process step with an isotropic component and the spacer structure comprises at least one point on the surface with a large solid angle opening towards the environment. Method of manufacturing an integrated circuit, including a regional removal of a spacer structure, wherein the removal is determined by a pattern density in the vicinity of the spacer structure.

### BACKGROUND

Integrated circuit fabrication involves creating features into a substrate, generally silicon, which results in various devices such as transistors and capacitors. The fabrication of transistors and capacitors are of particular importance in memory devices that use transistors to transfer charge and capacitors to store charge. Designers, however, are increasingly faced with shrinking circuit sizes. These shrinking sizes result in challenges in designing integrated circuits that require large capacitor size, which takes up a larger area on the circuit and is in conflict with shrinking circuit sizes.

In the processing of semiconductor devices methods for manufacturing and processing spacer structures are needed.

### BRIEF DESCRIPTION OF THE DRAWINGS

In the following schematic drawings, some embodiments of the invention are described as non-limiting examples, wherein

FIG. 1 shows a cross section of an initial structure as an example of a first embodiment;

FIG. 2 shows a cross section of the structures and the substrate according to FIG. 1 subjected to an etch process with an isotropic component;

FIG. 3 shows a cross section of the structures according to FIG. 2 after the etch process step with an isotropic component;

FIG. 4 shows a cross section of the structures according to FIG. 3 subjected to an anisotropic etching process;

FIG. 5 shows a cross section according to FIG. 4 after the anisotropic etching process;

FIG. 6 shows a cross section with a spacer structure;

FIG. 7 shows a cross section of an initial structure as an example of a second embodiment;

FIG. 8 shows a cross section of the structures according to FIG. 7 after the deposition of polymer material;

FIG. 9 shows a cross section of the structures according to FIG. 8 after the partial removal of the polymer material;

FIG. 10 shows a cross section of the structures according to FIG. 9 after etching with an isotropic component;

FIG. 11 shows a cross section of the structures according to FIG. 10 after the removal of the polymer material;

FIG. 12 shows a cross section of the structures according to FIG. 11 after anisotropic etching;

FIG. 13 shows a cross section with a spacer structure;

FIG. 14 shows a cross section of an initial structure as an example of a third embodiment;

FIG. 15 shows a cross section after an etching process step;

FIG. 15A shows a top view of the embodiment shown in FIG. 15;

FIG. 16 shows a cross section after the deposition of polymer material;

FIG. 16A shows a top view of the embodiment shown in FIG. 16;

FIG. 17 shows a cross section of a spacer structure;

FIG. 17A shows a top view of the spacer structure;

FIG. 18 shows an initial structure as a fourth embodiment in a top view;

FIG. 19 shows a top view of the structure according to FIG. 18 after the conformal deposition and etching of a spacer liner;

FIG. 20 shows a top view of the structure with a spacer structure;

FIGS. 21, 21A show a cross section and a top view of an initial structure as an example for a fifth embodiment;

FIGS. 22, 22A show a cross section and a top view of the stack according to FIG. 21, 21A with an a-Si layer;

FIGS. 23, 23A show a cross section and a top view of the stack according to FIG. 22, 22A with an irradiation step;

FIGS. 24, 24A show a cross section and a top view of the stack according to FIG. 23, 23A subjected to an etch process step with an isotropic component;

FIGS. 25, 25A show a cross section and a top view of the stack according to FIG. 24, 24A subjected to a further etch process step with an isotropic component;

FIGS. 26, 26A show a cross section and a top view of the stack according to FIG. 25, 25A subjected to a further etch process step with an isotropic component;

FIG. 27 shows a cross section of a further processing of the substrate using the spacer structures;

FIG. 28 shows a cross section of an initial structure as an example of the sixth embodiment;

FIG. 29 shows a cross section of the stack according to FIG. 28 after the deposition of a spacer liner;

FIG. 30 shows a cross section of the stack according to FIG. 29 after an anisotropic etching process step;

FIG. 31 shows a cross section of a structure to be subjected to the first embodiment of a pitch fragmentation technique;

FIG. 32 shows a cross section after the first process step of the first embodiment of the pitch fragmentation technique according to FIG. 31;

FIG. 33 shows a cross section of a structure to be subjected to the third embodiment of the pitch fragmentation technique;

FIG. 34 shows a cross section after the first process step of the third embodiment of the pitch fragmentation technique according to FIG. 33;

FIG. 35 shows a cross section after the second process step of the third embodiment of the pitch fragmentation technique;

FIG. 36 shows a cross section of a structure to be subjected to a third embodiment of a pitch fragmentation technique;

FIG. 37 shows a cross section after the first process step of the third embodiment of the pitch fragmentation technique according to FIG. 36;

FIG. 38 shows a cross section after the third process step of the third embodiment of the pitch fragmentation; and

FIG. 39 shows a cross section after the third process step of the third embodiment of the pitch fragmentation.

### DETAILED DESCRIPTION OF ILLUSTRATIVE EMBODIMENTS

In the following different embodiments are described in the context of the manufacturing of semiconductor devices. Examples for semiconductor devices are, e.g., memory chips such as DRAM chips, PC RAM chips or Flash-memory chips. Furthermore, microprocessors, integrated circuits, optoelectronic devices, microelectromechanical devices or biochips are further examples for semiconductor devices.

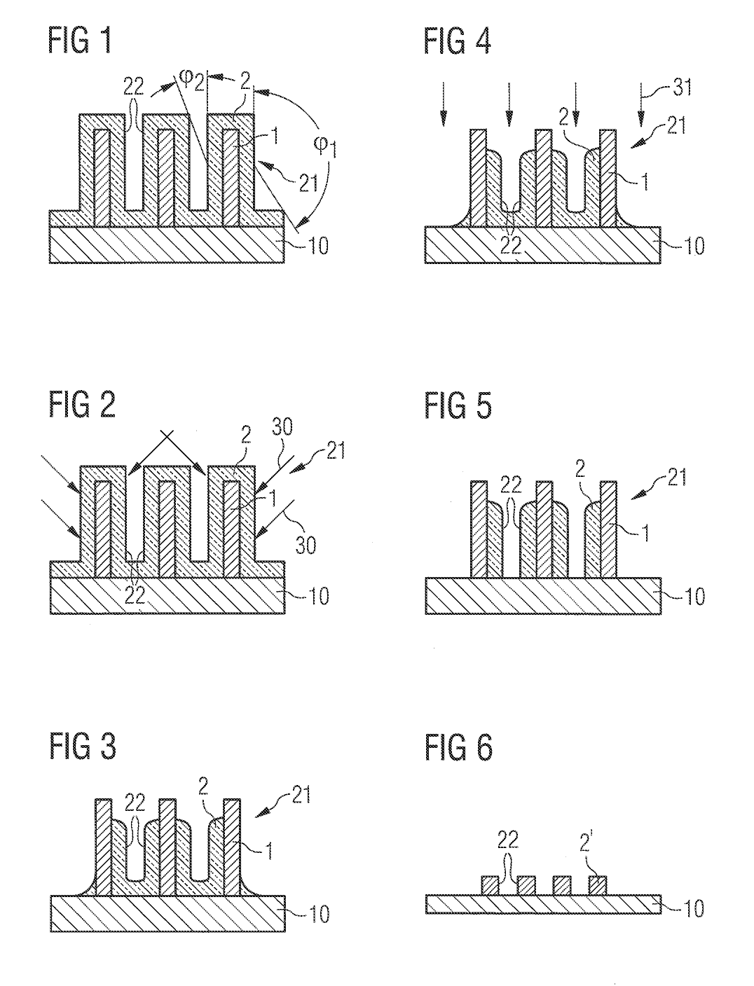

In FIG. 1 to 6 a first embodiment of a method which can be used in the manufacturing of a semiconductor device is described.

In FIG. 1 to 6 cross sections of structures on a substrate 10 are shown. As a person skilled in the art will recognize the shape of the structures is just one of many others.

The substrate 10 can comprise a wafer (e.g., made from silicon, germanium or an III-V material) as used in the manufacturing of semiconductor devices. The substrate 10 can comprise at least one layer, which may be prestructured. As a non limiting example, the substrate 10 is assumed here to be used in the manufacturing of semiconductor devices, such as, e.g., microprocessors, integrated circuits, memory chips, DRAM chips, PC RAM chips, Flash chips, biochips and microelectromechanical devices.

On the substrate 10 carrier structures 1 are positioned. The carrier structures 1 are covered by a spacer liner 2 from which a spacer structure can be manufactured. The covering of the carrier structures 1 with a spacer liner 2 is one possibility of a combination of carrier structures 1 and a spacer liner 2.

As will be described below, spacer structures can be manufactured in a number of ways.

The spacer structures 2 can be manufactured by the spacer techniques described below in FIG. 31 to 39. Using these techniques (pitch fragmentation) it is possible to manufacture small structures which are arranged on pitches below the effective resolution of the used lithography process, in the following labeled as “sublithographic”.

One possible use of spacer structures is the manufacturing of sublithographic structures in or on the substrate 10. Furthermore, spacer structures can be used in connection with pitch fragmentation techniques.

In the described embodiment of FIG. 1 the carrier structures 1, i.e., the height of the carrier structures 1, is relatively large compared to the vertical distance of the carrier structures 1, this leads to a dense arrangement. Furthermore, it is possible that pattern density of the structure 1 is higher than in the area surrounding the structures 1.

The spacer liner 2 covers the carrier structures 1. Therefore, points on the outer sides 21 of the spacer liner 2 are exposed to larger solid angle φ₁, than the points on the inner sides 22 of the spacer liner 2 (angle φ₂ ). Solid angles are measured in steradians. In one possible embodiment the first solid angle φ₁ can be larger by about 20% than the second solid angle φ₂. In yet another embodiment, the first solid angle φ₁ can be larger by about 10% than the second solid angle φ₂. Naturally, the Figures can only show a two dimensional representation of the solid angle. The accessibility of the etching medium can depend on the size of the solid angle. A relatively small solid angle might be smaller than a quarter sphere in a further embodiment.

As will become clear in the examples given below, the solid angles φ₁, φ₂ can depend on the position of a point on the physical location on a structure. This has physical consequences in case a large solid angle means that the point can be better accessed by, e.g., an etch medium with an isotropic component. The isotropic component means that the etch medium particles move in all directions, i.e., there is no preferred direction. For a point on a structure this implies that the larger the solid angle, the more isotropic etch medium can access this point. The person skilled in the art will recognize that a point which is, e.g., in a trench between structures separated by a small distance will have a small solid angle. Situations like this can occur, e.g., in dense patterns, like arrays. The point in the deep trench will be shadowed by the surrounding patterns.

A point which is facing a free area, e.g., a point on the outside of a dense pattern, has a larger solid angle. If both points are subjected to an etching medium, the etching results will be different, as they can depend on the size of the solid angles. The etching rate can be a function of the solid angles.

The geometric relationships are here just shown as an example using the three depicted carrier structures 1. The person skilled in the art understands that two, four or more structures can be used in manufacturing a structure. The spacer structures 1 do not have to be equidistant and the spacer structures 1 do not have to be of the same size or form.

In FIG. 1 it is further depicted that the carrier structures 1 with the spacer liners 2 form a relative dense pattern which is surrounded by free areas (e.g., support area) on the substrate 10 to the left and right, i.e., in the vicinity of the carrier structures 1 and the spacer liners 2. It can be seen that the size of the solid angles φ₁ and φ₂ depends on the pattern density. When the points on the spacer liner 2 open towards free space, the solid angle can be larger.

In a further embodiment the spacer structure is removed in regions, in which the distance to the closest adjacent spacer structure is at least about 2, especially about 3 times the spacer width on at least one side of the spacer structure measured perpendicular to the spacer. The removal of the spacer can depend on the solid angle and therefore on the accessibility of the etching medium.

In another embodiment the spacer structure is removed in regions, in which the distance to the closest adjacent spacer structure is larger than or equal to the height (i.e., the height before an etching process) of the spacer structure on at least one side of the spacer structure measured perpendicular to the spacer.

For the sake of simplicity the solid angles are not shown in all figures of the following embodiments.

FIG. 2 a subsequent process step is shown. The spacer liner 2 is subjected to an etch process 30 with an isotropic component. As can be seen in FIG. 2 the effect of the etching with an isotropic component depends on the density of the pattern, i.e., how close the carrier structures 1 are positioned relative to each other. The effect, e.g., the selectivity of the etching with an isotropic component also depends on the size of the solid angles φ₁ and φ₂ . In the regions with a larger solid angle φ₁ the rate of etching with an isotropic component is higher than in regions with the smaller solid angle φ₂.

In FIG. 3 it is shown that in the more exposed regions (large solid angle) the spacer liner 2 is at least partially more removed in the inner regions (e.g., array region) of the carrier structures 1 with the smaller solid angles. Due to the reduced progress of etching the spacer liner 2 is present at the inner walls 22 and between the carrier structures 1 on the substrate 10.

In FIG. 4 it is shown that the structures and the substrate of FIG. 3 are subjected to a second etch process step 31, here an anisotropic etching.

The result of the anisotropic etching 31 is shown in FIG. 5, i.e., the spacer liner 2 has been removed from the outer walls 21 so that the spacer liner 2 only remains between the carrier structures 1, i.e., the regions where points on the walls of the spacer liner 2 (or the carrier structure) have a smaller solid angle.

Subsequently, the carrier structures 1 are removed by a further etch process (see FIG. 6) so that only the spacer structures 2′, i.e., the remainders of the previous spacer liner 2, are present on the substrate 10. The spacer 2′ can now be used to structure the substrate 10 further.

In other embodiments, the anisotropic etch process step 31 can be performed before the isotropic etch process step 30. Furthermore, it is possible to use a combined step process, e.g., a process having an isotropic component and an anisotropic component at the same time.

In another embodiment which is analog to the one depicted in FIG. 1 to 6 the carrier structures comprise amorphous silicon (a-Silicon). The spacer liner 2 comprises SiO₂ or SiN. The a-Silicon layer can be so thick that after an etch process and the deposition of the spacer liner 2 an aspect ratio of at least about 2 exists. If, e.g., the carrier structures 1 have a width of about 35 nm, the spacer liner 2 has a thickness of about 35 nm and the distance between the spacer liner 2 surfaces is about 35 nm, the height of the carrier structures could be about 70 nm. But the aspect ratio could be higher such as about 3 (i.e., height of carrier structure about 105 nm) or about 4 (i.e., height of carrier structure about 140 nm).

The substrate 10 can comprise a layer of SiON on a thin a-Silicon layer.

In another embodiment of the method described in FIG. 1 to 6 the spacer liner etching is performed with a CHₓHal_{y} (Hal: Halogen such as F, Cl, Br, I) chemistry in oxide etch chamber. It is possible to generate an endpoint detection from the signal when the substrate is exposed.

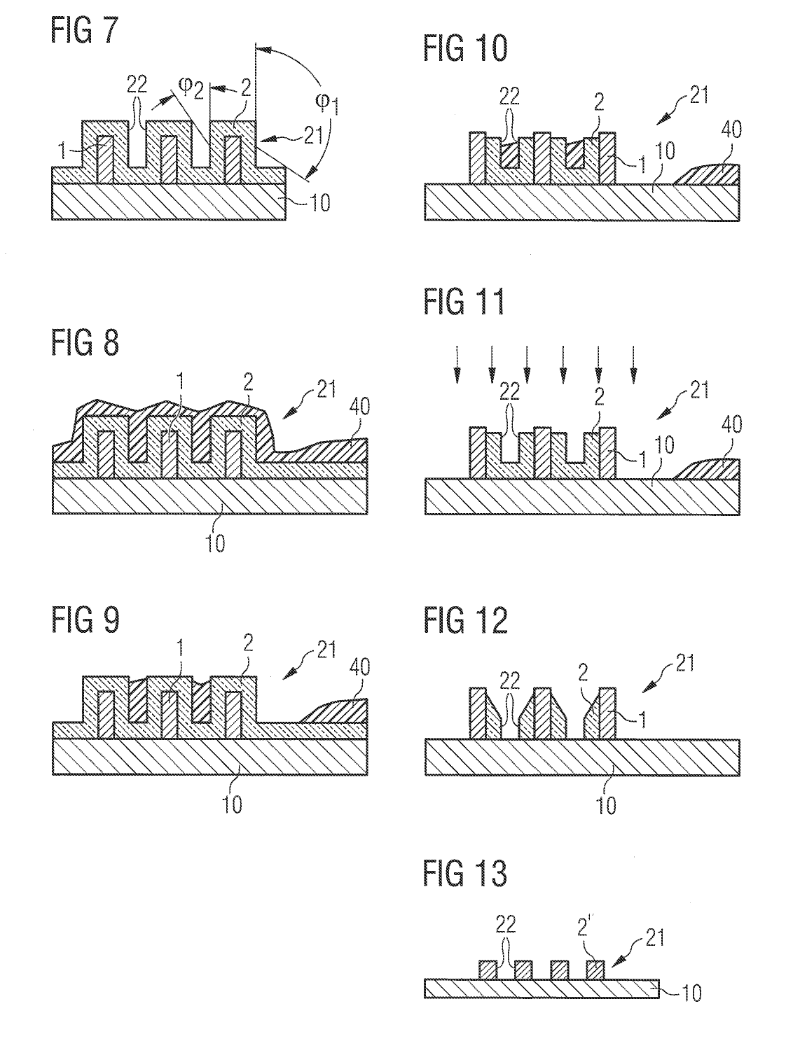

In FIG. 7 to 13 an example of a second embodiment is depicted. The initial structure in FIG. 7 is similar to the one described in connection with the first embodiment (see, e.g., FIG. 1). Like in the first embodiment, this initial structure comprises areas with a large free solid angle and regions with relatively smaller solid angles.

The description related to the geometry of the spacer liner 2 and the carrier structures 1 can, but does not have to be applied to the second embodiment. The relevant description applies.

The carrier structure 1 is covered with a spacer liner structure 2.

In FIG. 8 the situation is shown after an etching step in deposition mode. On the spacer liner 2 a polymer 40 has been deposited. The region within the dense carrier structures 1 (covered with spacer liners 2) is filled. In one embodiment the gaps between the carrier structures 1 are filled without voids.

An etching in deposition mode can comprise a plasma etching in which polymers are constantly formed but also constantly etched away. Depending on the process control, the deposition mode can be dominant so that the etching can be stopped. It is also possible that locally a strong etch is performed if the process parameters are not favorable for the deposition. Possible process parameters are etch molecule concentration, temperature, pressure, electrical field strength and/or RF Power.

In FIG. 9 the situation depicted in FIG. 8 has been subjected to an etch process with an isotropic component in which the polymer 40 is etched back. Due to the high aspect ratios some polymer remains in the gaps between the spacer structures. In FIG. 9 some polymer 40 residue is also present outside the carrier structure 1 pattern.

In FIG. 10 the situation after another etch process step with an isotropic component is shown. All regions which are not covered by polymer are predominantly etched. The spacer liner 2 is removed from corners and open regions.

In FIG. 11 the situation after the removal of the polymer by an etch process step is shown. This etching is selective to the spacer liner 2.

In FIG. 12 an anisotropic liner etch to remove the carrier structures 1 is depicted.

As a result a spacer structure 2′ as shown in FIG. 13 is obtained which can be used for further processing of the substrate 10.

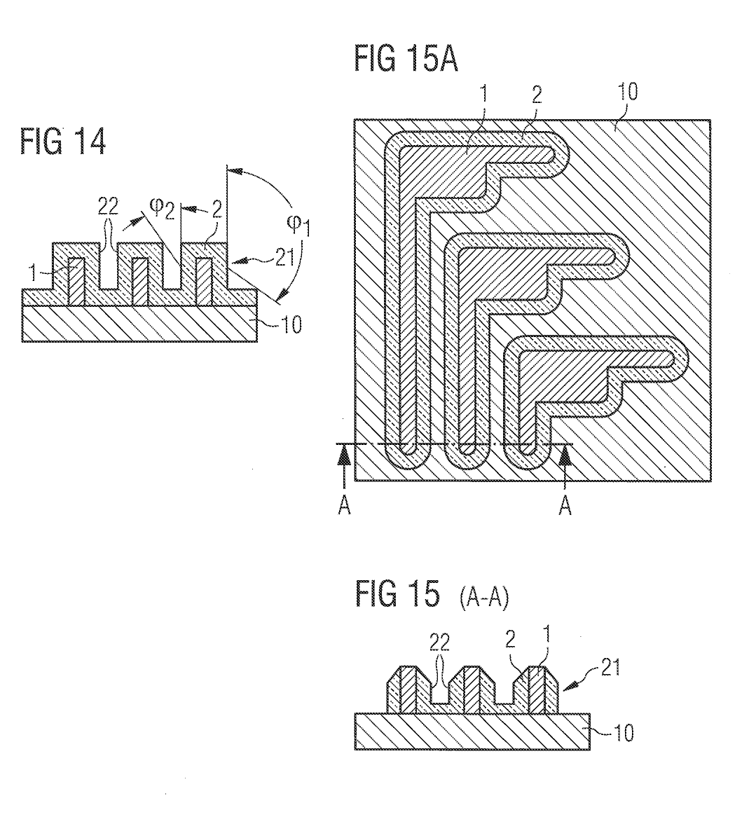

The third embodiment depicted in FIG. 14 to 17 is a variant of the second embodiment shown in FIG. 7 to 13. The person skilled in the art will recognize that the relevant description of the second embodiment also applies to the third embodiment.

FIG. 14 shows a similar initial structure as in FIG. 7. As in the previous embodiments the free solid angles φ are shown. The free solid angle φ₁ at the rim, i.e., opening towards the open space, is larger than the solid angle φ₂ at a point on the inner wall 22.

But unlike in the second embodiment the liner structure 2 is subjected to an etching (see FIG. 15) with an isotropic component. The liner structure 2 is removed from free spaces and thinned on especially exposed areas like, e.g., corners or line ends. Exposed in this context can also mean an area in which a point has a relatively large unobstructed solid angle (see description of the first embodiment, FIG. 14).

The outer walls 21 are covered with a thinner spacer liner 2 than the inner walls 22. As described in connection with the first embodiment, the unobstructed solid angle at a point of the inner walls 22 would be less than the one on the outer walls.

In FIG. 15A a top view is shown indicating the cross sectional view of FIG. 15.

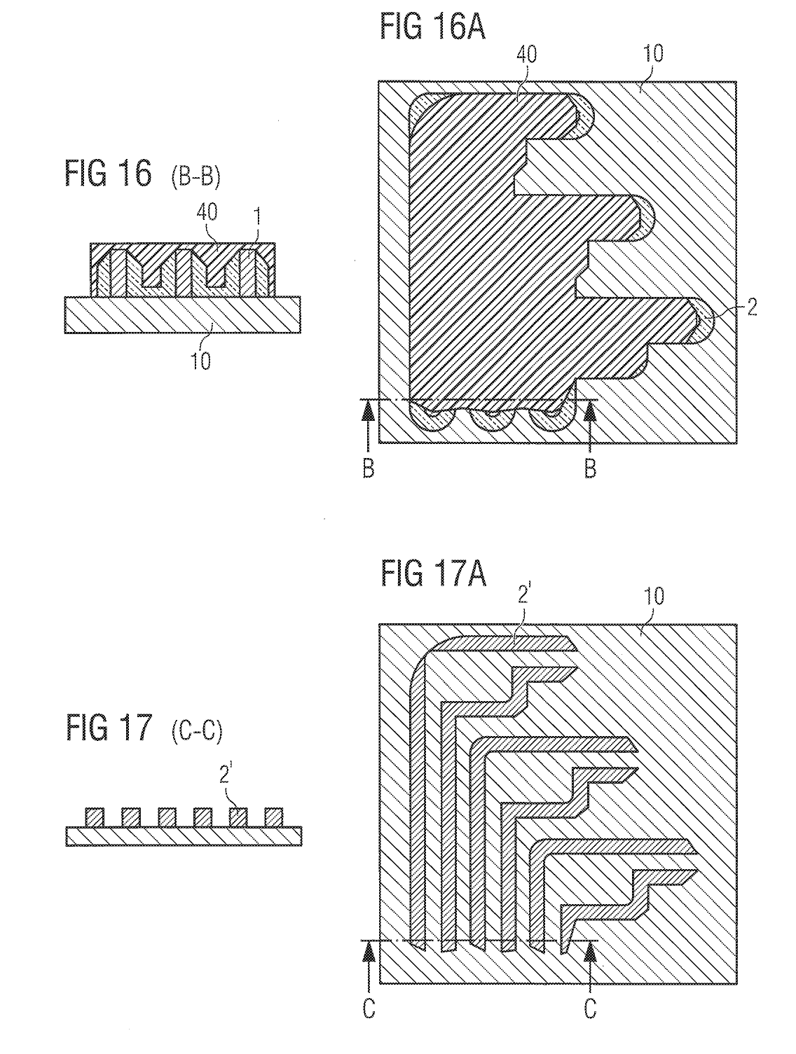

In FIG. 16 the situation is shown after the process parameters are changed to a polymerizing etching in which more polymer 40 is deposited in regions in which the spacer liner 2 is relatively thick. Less polymer 40 is formed in exposed regions.

The spacer liner 2 is not as well protected in the exposed regions and is removed almost completely in subsequent etching process steps (not shown here). Small residuals can be removed in a later process stage (not shown here).

In FIG. 16A a top view of the situation in FIG. 16 is shown. The area covered by polymer 40 leaves small residuals at the ends of the finger like protrusions. In an etch step those endportions can be selectively removed by an etch step. After removal of the polymer 40 and the carrier structure 1, the situation is reached as shown in FIG. 17A. FIG. 17 shows a cross section of the resulting spacer structure 2′ as indicated in FIG. 17A.

The top views in FIG. 16A and 17A are examples for more complex spacer structures 2′ which are in principle also applicable to other embodiments.

In another embodiment which is analog to the one depicted in FIG. 1 to 6 the carrier structures comprise a-Silicon. The spacer liner 2 comprises SiO₂ or SiN. The a-Silicon layer can be so thick that after an etch process and the deposition of the spacer liner 2 an aspect ratio of at least 2 exists. If, e.g., the carrier structures 1 have a width of about 35 nm, the spacer liner 2 has a thickness of about 35 nm and the distance between the spacer liner 2 surfaces is about 35 nm, the height of the carrier structures could be about 70 nm. But the aspect ratio could be higher such as about 3 (i.e., height of carrier structure about 105 nm) or about 4 (i.e., height of carrier structure about 140 nm).

The substrate 10 can comprise a layer of SiON on a thin a-Silicon layer.

In further embodiments which are analog to the ones depicted in FIG. 7 to 17 the carrier structures comprise a-Silicon. The spacer liner 2 comprises SiO₂ or SiN. The a-Silicon layer can be so thick that after an etch process and the deposition of the spacer liner 2 an aspect ratio of at least about 2 exists. If, e.g., the carrier structures 1 have a width of about 35 nm, the spacer liner 2 has a thickness of about 35 nm and the distance between the spacer liner 2 surfaces is about 35 nm, the height of the carrier structures could be about 70 nm. But the aspect ratio could be higher such as about 3 (i.e., height of carrier structure about 105 nm) or about 4 (i.e., height of carrier structure about 140 nm ).

The substrate 10 can comprise layer of SiON on a thin a-Silicon layer.

In another embodiment, an isotropic sputter etching (e.g., an etching from above with an etching effect in all directions, so that there is a shadowing effect of neighboring structures) might be used before the polymer deposition.

In further embodiments of the methods described in FIG. 7 to 17 the spacer liner etching is performed with a CHₓHal_{y} (e.g., Hal: F, Cl, Br, I) chemistry in oxide etch chamber. It is possible to generate an endpoint detection from the signal when the substrate 10 is exposed.

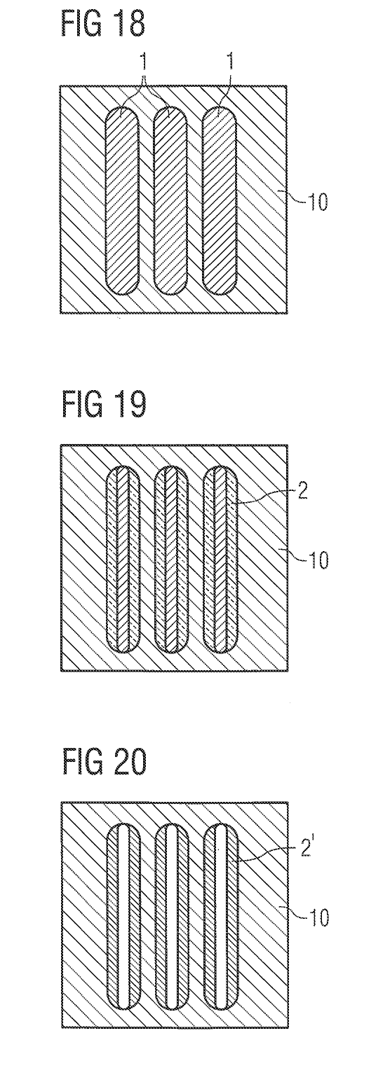

A fourth embodiment is described in connection with FIG. 18 to 20. The carrier structure 1 in the first three embodiments were protruding (e.g., ridge like structures) from a substrate 10.

In the fourth embodiment the carrier structure comprises groove like structures in the substrate 10. The person skilled in the art will recognize that these types of carrier structures 1 are not excluding each other, i.e., in the manufacturing of a semiconductor device both types of carrier structures can be combined.

In FIG. 18 three grooves are shown as carrier structures 1. The width of the grooves can be varied. One example would be a width between about 2.5 and about 4 of a line type carrier structure 1.

FIG. 19 shows the situation after the conformal deposition of a spacer liner 2 on the walls of the grooves and an etching process step with an isotropic component. Since the solid angle towards the surrounding space is larger at the ends of the grooves than at the walls, the etching ions can attack the spacer liner 2 more efficiently at those ends. In FIG. 19 it is shown that the spacer liner 2 is essentially removed at the ends of the grooves but still present on the walls after the etching with an isotropic component.

In FIG. 20 it is depicted that the spacer liner 2 can be transferred as spacer structure 2′ by further processes, such as etching the surrounding substrate material anisotropically.

The spacer structures 2′ can then be used to further process the substrate 10.

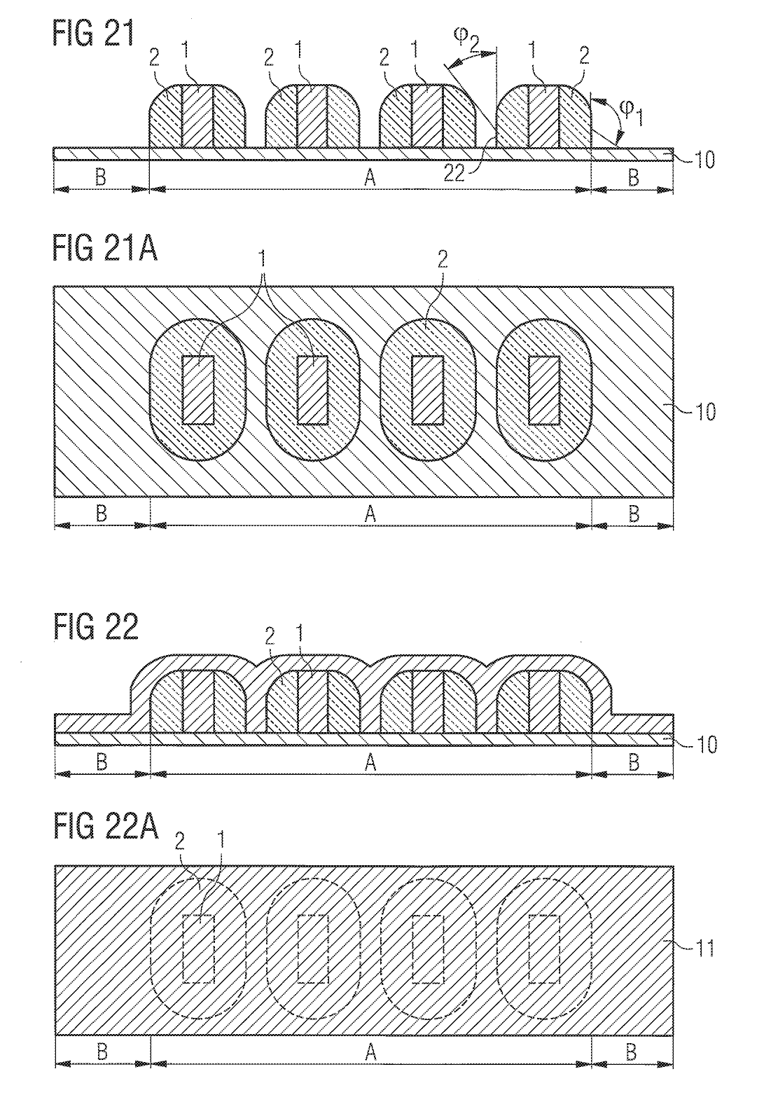

In FIG. 21 to 26 a fifth embodiment is depicted in a schematic way.

Demonstrating the embodiment of an initial structure for the fifth embodiment is shown in FIGS. 21 and 21A. FIG. 21 is a cross sectional view, FIG. 21A is a top view. Carrier structures 1 are lined with a spacer liner 2, both are situated on a substrate 10. The substrate 10 can be prestructured and can comprise at least one structured or unstructured layer. In FIGS. 21, 21A the spacer liner 2 is already removed from the top section of the carrier structure 1. The view of the carrier structures 1 and the spacer liner 2 shows an array section A in the middle, i.e., the carrier structures 1 are part of an array A, whereas towards the rim a support area B is shown. In the array A the structures are much more densely placed than in the support area B. A solid angle φ₁ exposed to the support area (or another relatively free area) is larger than a solid angle φ₂ at the inner wall 22.

The person skilled in the art will recognize that the embodiment is also applicable for other structures.

In one embodiment analog to FIGS. 21, 21A the carrier structure 1 comprises polysilicon. The spacer liner 2 comprises an oxide layer. It is also possible that the carrier structure 1 comprises carbon or Si₃N₄ (using a-Si or TiN as substrate). The substrate 10 can comprise a nitride liner.

FIGS. 22 and 22A the situation after a subsequent process step is described. The stack according to FIGS. 21, 21A is covered by an a-Si or poly-Si layer 11 overfilling the array area A. Even though the Si layer 11 covers the spacer liner 2 and the carrier structures 1, in the top view the relevant structures are indicated by dashed lines.

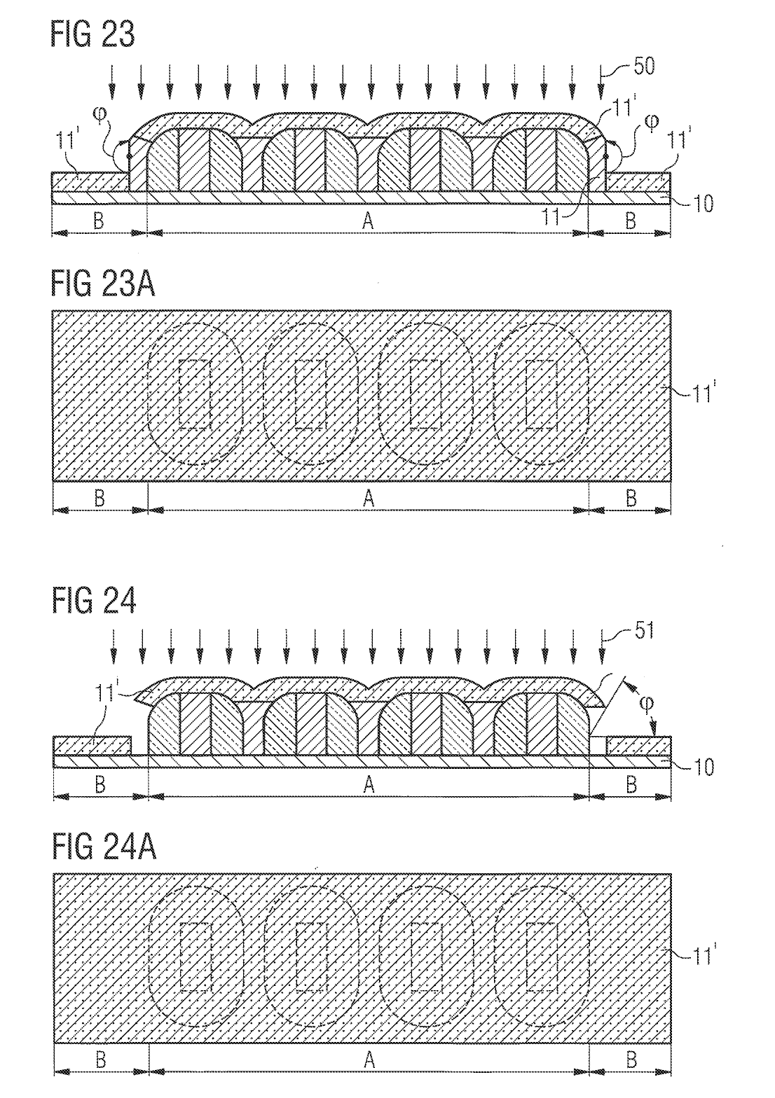

In FIGS. 23 and 23A a subsequent process step is depicted, i.e., an irradiation. In one embodiment the irradiation 50 can be an implantation, especially a boron implantation with boron and/or a boron compound. When performed essentially perpendicularly, this irradiation alters or modifies the Si layer 11 into irradiated parts 11 ′ and non-irradiated parts 11. The non-irradiated parts 11 in the embodiments best shown in FIG. 23 are shadowed by a region which is irradiated. The two sections of non-irradiated parts 11 facing the support area B, i.e., the oxide liner 11 ′ at the outer rim is open to the array B, and the non-irradiated parts 11 between the carrier structures 1 (i.e., in the middle of the array A) are not exposed. A point at the surface of the non-irradiated part 11 facing the support area B has free solid angles φ₁, whereas the non-irradiated parts 11 between the carrier structures have no free solid angle. For demonstration purposes a free solid angle φ is indicated in FIG. 23. Even though the oxide layer 11 covers the spacer liner 2 and the carrier structures 1, in the top view the relevant structures are indicated by dashed lines.

In FIGS. 24, 24A a subsequent process step, i.e. a wet etch processing step with isotropic component is shown. The wet etch processing step 51 is selective to the irradiated part 11′ of the Si layer 11, thereby etching away the non-irradiated parts 11 (i.e., the unmodified or unaltered material) exposed to the support area B. Due to the free solid angle of those parts the etching agent can attack the material there, resulting in an under etch at the rim of the array area A. The person skilled in the art will recognize that in other embodiments, the altered parts might be selectively etched.

In one embodiment the wet etching agent can be NH₄OH and/or KOH or other alkaline chemicals.

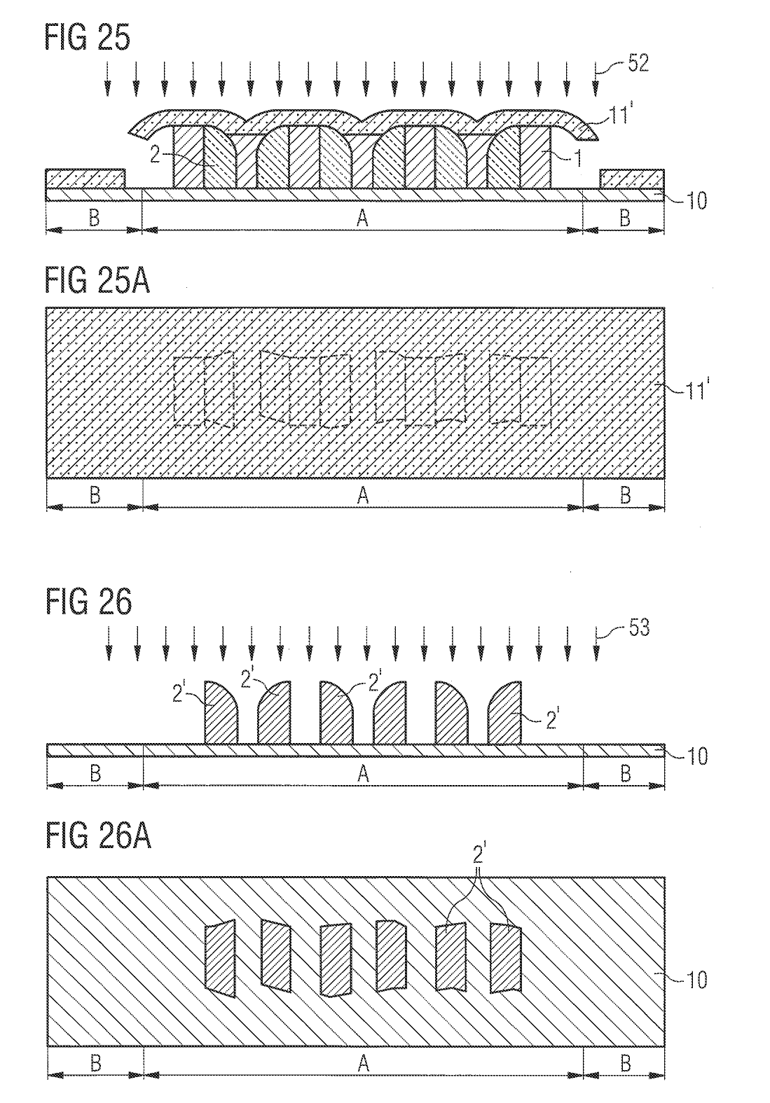

In FIG. 25, 25A a further processing step is depicted, i.e., a wet etch process stripping 52 the oxide of the spacer liner 2 exposed to the surrounding area (i.e., exposed to the array area B). Using this embodiment, the outer spacer structures 2 can be removed selectively.

In FIGS. 26, 26A a further processing step is depicted, i.e., the removal of the oxide layer 11 and the removal of the polysilicon of the carrier structures 1 by an RIE isotropic stripping. The remaining spacer structures 2′ can now be used to structure the substrate 10 below in further process steps. The stripping can be part of a double-patterning process to structure the substrate 10.

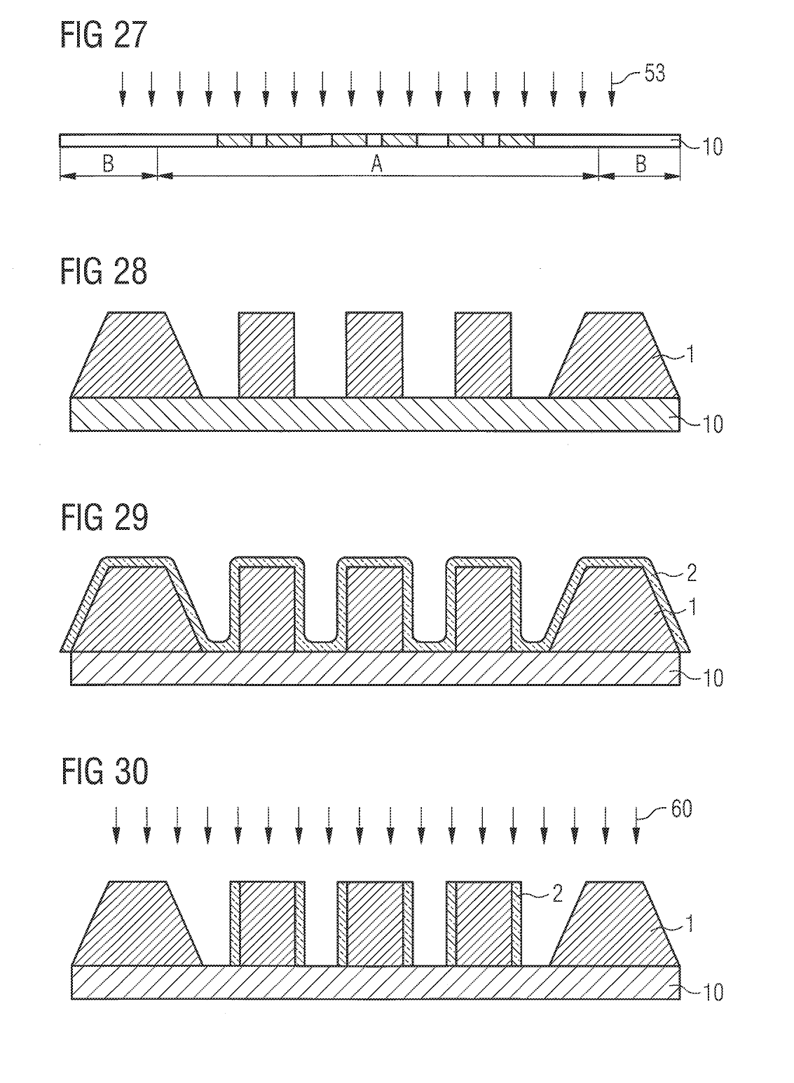

In FIG. 27 a cross section is shown which gives an example of how the spacer structures 2′ can be used for further processing of the substrate 10 by etch, and removal of the spacer.

In FIG. 28 to 30 a sixth embodiment is depicted by cross sections.

In FIG. 28 a cross section of the initial structure of the sixth embodiment is shown. As in the fifth embodiment an array region A with carrier structures 1 is present. At the rim of the array region A, i.e., next to the support region B (i.e., a region with a wider distribution of structures), carrier structures 1 are formed having tapered sidewalls. The carrier structures 1 towards the middle of the array region A have essentially straight sidewalls, i.e., the tapering angle is essentially about 0°.

One method for manufacturing tapered (e.g., tapering angle larger than about 0°, measured from a perpendicular line) sidewalls is an etch process (not depicted here) with a strong microloading dependency. Parameters to influence the microloading are the resist type of a mask and/or the etch parameters (ion energy, temperature and/or pressure etc.) This is followed by a removal of a spacer on the top of the taper which will be removed from the tapered surface by an overetch. In the denser array region A the spacer thickness remains as deposited.

The formation of polymer etched sidewalls can be higher at larger available solid angles (e.g., at line ends into open areas, or isolated lines, or at an array edge, or in general at edges of larger spaces; or additional or alternatively at edges with more dark environment) with more polymer formation on sidewalls during etch and therefore formation of a progressing protective sidewall of polymer. A further alternative is the intentional local taper of resist profiles by intentionally low local image contrast by special mask layout design, e.g., by not applying assist features.

In FIG. 29 it is shown that the carrier structures 1 (tapered and non-tapered) are covered with a liner structure 2.

In FIG. 30 it is shown that the stack according to FIG. 29 is subjected to an anisotropic spacer etch process 60, e.g., an ion assisted etch process. The spacer etch will remove the spacer liner at the tapered carrier structures at the rim more than on the sidewalls of the straighter sidewalls.

As mentioned above, the spacer structures can be manufactured by any technique, such as pitch fragmentation with spacers. In FIG. 31 to 39, examples for different spacer techniques are given.

In FIG. 31 a cross section of a general structure 500 on a substrate 1000 in a semiconductor device is depicted. This structure 500 will be used to demonstrate an embodiment of a pitch fragmentation technique, i.e., a line by spacer technique (or a pattern by spacer technique if a more complex structure is used).

The general structure 500 shown in FIG. 31 might represent among other possibilities a line in a memory chip or a microprocessor or any other integrated circuit. The structure could also represent a line in an optoelectronic device or a microelectromechanical device (MEMS). The person skilled in the art will recognize that the pitch fragmentation techniques described here are not limited to straight lines but can be used to manufacture more complex patterns.

In the embodiment of the pitch fragmentation according to FIG. 31, the initial structure 101 is lined with a sidewall structure 102 adjacent to the initial structure 101. The area of the substrate 1000 covered by the initial structure 101 is indicated by 100, the area covered by the sidewall structure 102 are indicated by 200.

The area 300 not covered by the initial structure 101 and the sidewall structure 102 remains free of material on its surface.

In the line by spacer technique shown, e.g., in FIG. 31 the area 100 covered by the initial structure 101 and the area 300 are transferred into the substrate 1000. Therefore, the initial structure 101 has to be removed, e.g., by an etching process which is selective to the sidewall structures 102 and the substrate 1000.

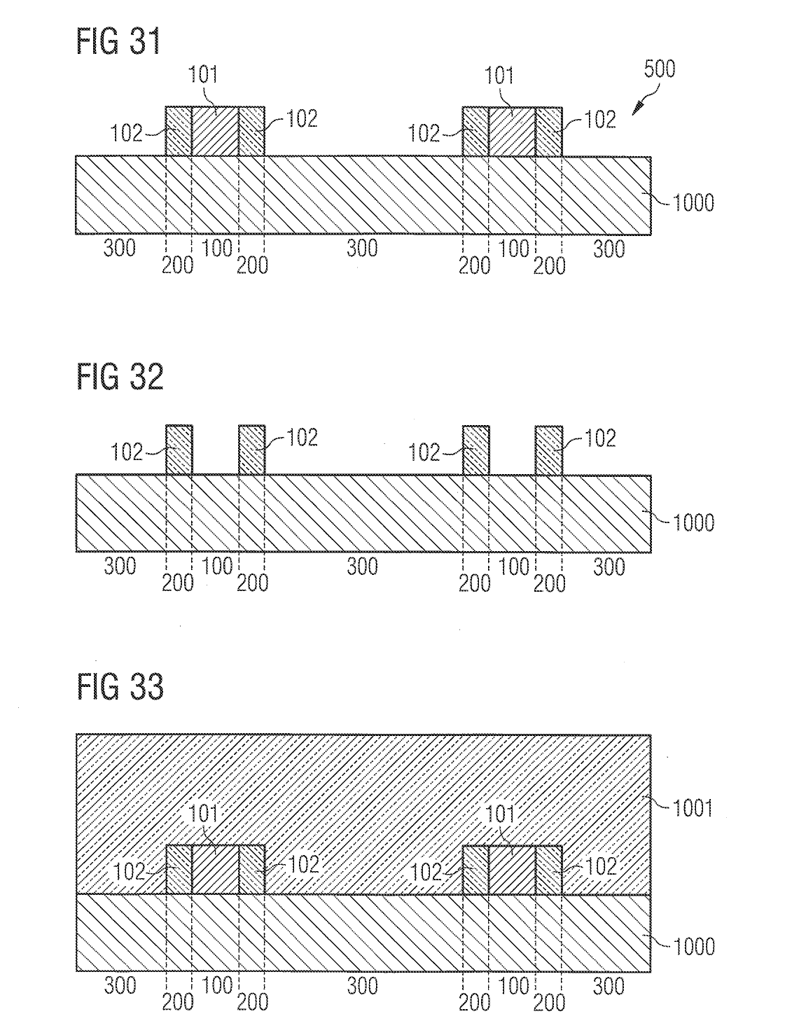

In FIG. 32 it is shown that only the sidewall structures 102 remain as spacer structures, since the spacer structures 102 have a relatively small width. A sublithographic pitch (i.e., a dimension of a pitch which is smaller than the capability of a certain illumination source) can be achieved due to the fact that each initial structure 101 has two sidewalls 102, thereby doubling the density of structures. As mentioned above, other dimensions than sublithographic pitches are feasible.

It will be understood by the person skilled in the art that the substrate 1000 does not have to be a single material but it might comprise structured layers.

In FIG. 33 a variation of the embodiment of FIG. 31 is shown in which a fill technique is used to transfer the area 300 and 100 into the substrate 1000. In this embodiment the area 300 is filled by some material. Starting with the layered stack as in FIG. 33, a layer 1001 is deposited, covering the initial structure 101, the sidewall structure 102 (i.e., the spacer) and the area 300.

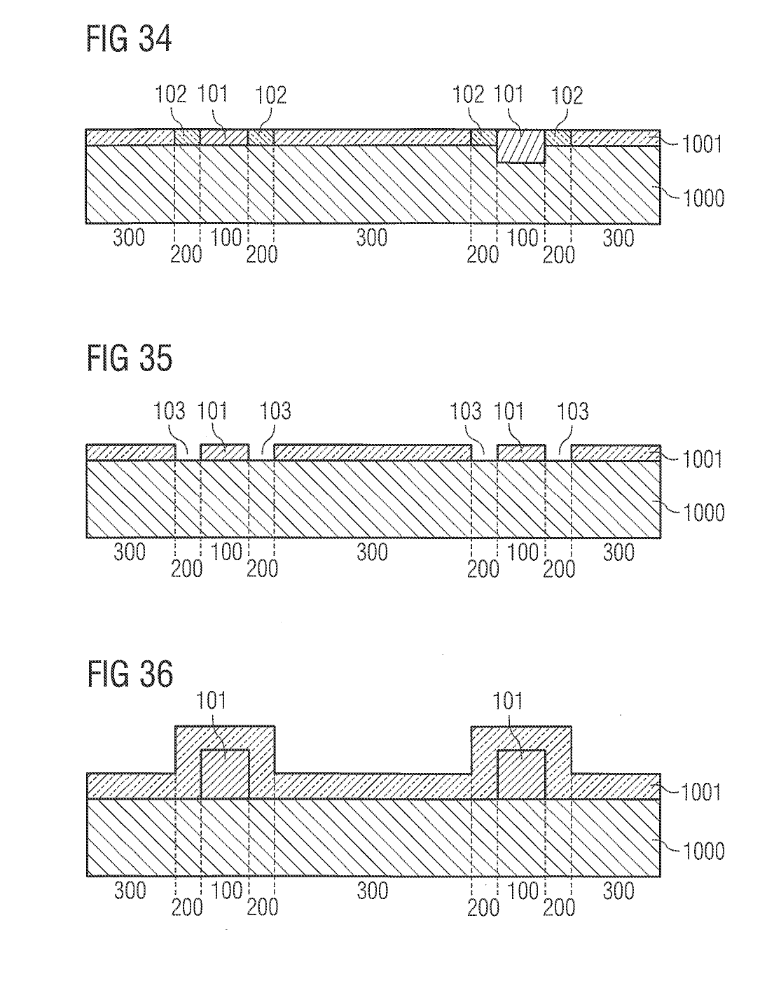

This stack is then recessed, e.g., by etching or CMP as shown in FIG. 34. Subsequently, the spacer structures 102 are removed, e.g., by etching the spacers 102 selectively to the initial structures 101 and the layer in area 300. Now the lines (or the pattern) formed by the spacer structure 102 can be transferred into the substrate 1000. This technique transfers the inverse pattern of the spacers into the substrate, i.e., it is the inverse pitch fragmentation technique of line by spacer.

This is shown in FIG. 35. The spacers 102 are removed by an etching process so that openings 103 are created. The remains of the layer 1001 and the initial structure 101 form a mask.

Another fill technique is a line by liner fill (or pattern by liner fill). In FIG. 36 an initial structure 101 is covered by a first layer 1001. The first layer 1001 lines, among other areas, the sidewalls of the initial structure 101. Therefore, the sidewall structures covering the areas 1001 are made by a liner material, rather than a spacer. A spacer etch is not required in this embodiment.

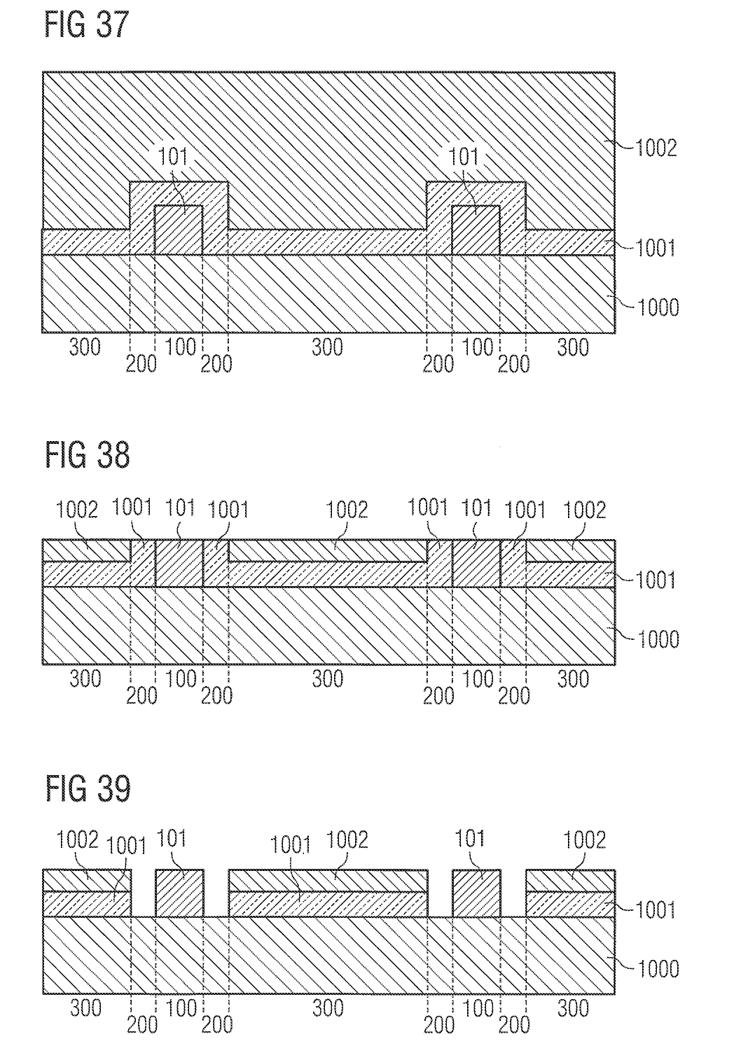

Subsequently, the stack shown in FIG. 36 is covered with a second liner 1002 as shown in FIG. 37.

Subsequently, the second layer 1002 is recessed or planarized as indicated in FIG. 38. In FIG. 39 it is shown that the liner material from the first layer 1001 is then removed, e.g., by an anisotropic etching which is selective against the material of the initial structure and the material of the second liner.

The persons skilled in the art will recognize that the pitch fragmentation techniques can be used more than once in an area leading to higher order pitch fragmentations, i.e., ever smaller structures can be manufactured. Furthermore, it is possible to exploit different selectivities between materials to define combinations of regions or subregions to define the pattern to be transferred into the substrate.

In addition, the person skilled in the art will recognize that the embodiments of the pitch fragmentation techniques can be modified in many ways and can be used in different combinations and with all kinds of material. The principles of the pitch fragmentations are not exhaustively covered by the examples given here.

In the present description of different embodiments, the term process step was used. The person skilled in the art will note that term process step can comprise more than one particular processing, e.g., etching. As was indicated in the description above sometimes more than one sub-step is described together as one process step. Furthermore, it is clear that between two process steps other processes or sub-steps might be applied.

Furthermore, the different process steps in the embodiments described are examples. The person skilled in the art will recognize that individual process steps of one embodiment can be combined with individual process steps from another embodiment.

The embodiments described above refer to methods and the intermediate structures which are manufactured at different stages of the methods. Even if the description refers to a method, the description is also intended to describe the intermediate structures.

What is claimed is:

1. A method for processing at least one spacer structure in a manufacturing process of a semiconductor device, the method comprising:
subjecting the at least one spacer structure to at least one etch process with an isotropic component such that the spacer structure comprises at least one point on the spacer structure with a first solid angle opening towards the environment, the at least one first point being exposed to the first solid angle which is larger than a second solid angle for a second point on the spacer structure.

2. The method according to claim 1, wherein the at least one etch process with the isotropic component selectively etches regions of the spacer structure comprising at least one point on the surface with a large solid angle.

3. The method according to claim 2, wherein the at least one etch process with the isotropic component at least partially removes the regions of the spacer structure comprising at least one point on the surface of the spacer structure with a large solid angle.

4. The method according to claim 1, further comprising performing an anisotropic etch before or subjecting the at least one spacer structure to the at least one etch process with the isotropic component.

5. The method according to claim 1, wherein the at least one etch process has an anisotropic component.

6. The method according to claim 1, further comprising depositing a polymer layer at least partially on the spacer structure before the at least one etch process with the isotropic component.

7. The method according to claim 6, wherein the polymer layer is at least partially anisotropically etched.

8. The method according to claim 1, further comprising performing an irradiation to alter material properties of a layer at least partially covering the spacer structures, wherein the at least one etch process with the isotropic component etches only the altered or unaltered portions of the layer.

9. The method according to claim 8, whereby the irradiation comprises an implantation.

10. The method according to claim 9, wherein the irradiation comprises implantation boron or a boron compound.

11. The method according to claim 8, wherein the at least one etch process with the isotropic component comprises a wet etch with an alkaline chemistry.

12. The method according to claim 1, wherein the at least one spacer structure is coupled with at least one carrier structure.

13. The method according to claim 12, wherein the at least one carrier structure comprises polysilicon, carbon, a polymer, silicon nitride or an oxide.

14. The method according to claim 12, wherein the at least one carrier structure comprises a ridge-like structure and/or a groove-like structure.

15. The method according to claim 12, wherein a ratio between a height of the at least one carrier structure and a closest distance to an adjacent carrier structure is greater than 2.

16. The method according to claim 1, wherein the at least one spacer structure comprises at least one of SiO₂, Si, carbon, a polymer, Si—N, Ti—O, Ti—N, Ta—N, Ge—O and SiON.

17. The method according to claim 1, wherein the at least one etch process with the isotropic component comprises etching with a CHₓHal_{y} chemistry, a NH₄OH chemistry or a KOH chemistry.

18. The method according to claim 1, further comprising determining a process time for the at least one etch process with the isotropic component, wherein an endpoint detection provides a signal when a region has been etched completely.

19. The method according to claim 1, further comprising:
at least partially covering the at least one spacer structure with an overfill layer; and
subsequently subjecting the at least one spacer structure to an irradiation.

20. The method according to claim 19, wherein the overfill layer comprises germanium or polysilicon.

21. The method according to claim 19, wherein an essentially vertical portion of the overfill layer is less altered by the irradiation than an essentially horizontal portion of the overfill layer.

22. The method according to claim 21, wherein the essentially vertical portion of the overfill layer is subjected to an etch process step with an isotropic component.

23. The method according to claim 22, wherein the overfill layer is at least partially removed after the etch process step with the isotropic component.

24. The method according to claim 12, further comprising:
removing the at least one carrier structure; and
using the at least one spacer structure to further structure a substrate below the at least one spacer structure.

25. The method according to claim 24, wherein the at least one spacer structure is used to generate sublithographic patterns.

26. The method according to claim 1, wherein the at least one spacer structure is manufactured by a spacer technique being at least one of a line-by-spacer technique, pattern-by-spacer technique, line-by-fill technique, pattern-by-fill technique.

27. The method according to claim 12, wherein the carrier structure comprises at least one surface that is slanted relative to a substrate.

28. The method according to claim 27, wherein the slanted surface is manufactured by using an etch process with a strong micro loading dependency.

29. The method according to claim 1, wherein at least one spacer liner with at least one slanted surface is subjected to an anisotropic etch process step to remove a spacer at least partially.

30. The method according to claim 29, wherein the at least one spacer structure is removed from at least one carrier structure by an anisotropic etch process step.

31. A method of manufacturing an integrated circuit, the method comprising:
performing a regional removal of a spacer structure, wherein the regional removal is determined by a pattern density in a vicinity of the spacer structure.

32. The method according to claim 31, wherein the spacer structure is formed at a sidewall of a carrier structure.

33. The method according to claim 31, wherein the spacer structure is removed in regions, in which a distance to a closest adjacent spacer structure is at least two times a spacer width on at least one side of the spacer structure measured perpendicular to the spacer structure.

34. The method according to claim 31, wherein the spacer structure is removed in regions, in which the distance to the closest adjacent spacer structure is larger than or equal to a height of the spacer structure on the at least one side of the spacer structure measured perpendicular to the spacer structure.

35. The method according to claim 31, further comprising:
depositing a cover layer onto the spacer structure;
modifying properties of the cover layer in a top portion by implanting particles; and
selectively removing non-implanted portions of the cover layer, thereby exposing regions of the spacer structure,
wherein the regional removal of the at least one spacer structure is performed through exposed regions of the cover layer.

36. The method according to claim 35, wherein the cover layer comprises polysilicon or amorphous silicon.

37. The method according to claim 36, wherein the selective removal of the non-implanted portions of the cover layer comprise an alkaline wet etch step.

38. The method according to claim 31, wherein the spacer structure is removed by a dry etch process with an isotropic component.

39. The method according to claim 31, wherein the regional removal comprises a reactive ion etching step having a removal rate of material forming the spacer structure lower in areas of densely spaced spacer structures compared to areas of isolated spacer structures.

40. The method according to claim 39, wherein a difference in the removal rate is caused by a shadowing effect of a carrier structure, the shadowing effect being caused by small solid angles.

41. The method according to claim 31, further comprising:
providing carrier structures having a first tapering angle in regions of isolated carrier structures and a second tapering angle in regions of dense carrier structures; and
forming the spacer structures at sidewalls of carrier structures,
wherein the first tapering angle, in the regions of isolated carrier structures is higher than the second tapering angle in regions of dense carrier structures, wherein each tapering angle is measured as a deviation from perpendicular.

42. The method according to claim 41, wherein the tapering angle in regions of dense carrier structures is approximately 0 degrees.

43. The method according to claim 41, wherein the tapering angle in regions of isolated carrier structures is larger than 25 degrees.

44. The method according to claim 41, wherein the regional removal of the spacer structure comprise an anisotropic etching step.

45. An intermediate structure with at least one spacer structure, wherein the at least one spacer structure comprises at least one point on a surface with a first solid angle opening towards an environment with at least a first point being exposed to the first solid angle which is larger than a second solid angle for a second point on the at least one spacer structure.

46. The intermediate structure according to claim 45, wherein the at least one spacer structure comprises at least one tapered surface.

47. The intermediate structure according to claim 46, wherein the at least one tapered surface is positioned adjacent a periphery or edge of an array of lines.
